(19) United States
(12) Patent Application Publication
(10) Pub. No.: US 2017/0047142 A1
(43) Pub. Date: Feb. 16, 2017

(54) USE OF A VITRIMER-TYPE THERMOSETTING RESIN COMPOSITION FOR MANUFACTURING ELECTRICAL INSULATION PARTS

(71) Applicant: Arkema France, Colombes (FR)

(72) Inventors: Jean-Pierre Disson, Vernaison (FR); Christophe Duquenne, Paris (FR); Michel Melas, Verneuil En Halatte (FR)

(73) Assignee: Arkema France, Colombes (FR)

(21) Appl. No.: 15/306,010

(22) PCT Filed: Apr. 16, 2015
(86) PCT No.: PCT/FR2015/051034

§ 371 Date: Oct. 21, 2016

(30) Foreign Application Priority Data
Apr. 24, 2014 (FR) 1453679

(51) Int. Cl. H01B 3/40; H01L 21/56; H05K 1/03; C08G 59/42; C08G 59/24; C08G 59/68; C08K 3/00; H01L 23/29; H05K 3/00

(52) U.S. Cl. CPC H01B 3/40; H01L 23/295; H01L 21/565; H05K 1/0373; H05K 3/0014; C08G 59/245; C08G 59/686; C08K 3/0033; C08G 59/4238

(57) ABSTRACT

The present invention relates to the use, for manufacturing electrical insulation parts, of a composition including, in addition to an epoxy-type thermosetting resin and a hardening agent, at least one organic catalyst having a vitrimer effect. Said composition allows the production of vitrimer resins, i.e., resins that are deformable in the thermoset state, which have properties that are suitable for use in electrical insulation parts. The invention also relates to a method for preparing electrical insulation parts using the aforementioned composition.

### FIELD OF THE INVENTION

The present invention relates to the use, in the manufacture of electrical insulation parts, of a composition including, apart from a thermosetting resin of epoxy type and a curing agent, at least one vitrimer-effect nonmetallic organic catalyst. This composition makes it possible to manufacture vitrimer resins, that is to say resins deformable in the thermoset state, which exhibit properties suitable for use in electrical insulation parts.

### TECHNICAL BACKGROUND

Electrical insulators are electrical engineering parts intended to fix, maintain or support bare electrical conductors. Insulators are found in particular on high voltage lines, where they provide the insulation between the conductors and the pylons. Insulators are also employed to insulate connectors of any size, which range from high voltage transformer connectors to connectors of small electronic circuits, such as, for example, of the small cable manufacturing plant in vehicles.

Mention may in particular be made, among the different materials used in the manufacture of these insulators, of thermoset resins of epoxy type, which are obtained from an epoxy resin formulation, a curing agent and generally a catalyst of tertiary amine type, according to a polycondensation process which has the advantage of not generating liquid or gaseous by-products. These thermoset resins make possible the molding of complex parts without formation of bubbles liable to damage the dielectric stiffness of the insulating material. This molding is, for example, carried out by gravity casting or by low-pressure injection. They can also be used in composite parts and more particularly for the impregnation of fibers in a process for the manufacture of insulators by filament winding. These epoxy resins are also used in the form of adhesives, of seals, of coatings or of sealing compounds. They make it possible to obtain materials exhibiting a high volume resistivity and surface resistivity.

The choice of an epoxy resin formulation is based in particular on the dielectric properties which it is desired to obtain and also on the physical, chemical and mechanical resistance which this material has to exhibit under the conditions of use envisaged (temperature, humidity, vibrations, and the like). The selection of the appropriate formulation also takes into account the conditions of curing of the resin, which must not release too much heat, shrink or develop internal stresses.

The epoxy resin formulations normally include fillers, in the fibrous or nonfibrous form, which make it possible to improve the mechanical properties and the heat dissipation of the material. They can be inorganic fillers, such as silica, alumina or glass, or organic fillers, such as poly(ethylene terephthalate).

Mention may in particular be made, as examples of epoxy resin formulations used to produce electrical insulation systems, of those described in the document WO 2010/031445, which comprise an epoxy resin, a curing agent, an inorganic filler and optionally additives, including a catalyst for facilitating the reaction between the epoxy resin and the curing agent. The catalyst is preferably chosen from tertiary amines or substituted imidazole compounds.

The document WO 99/43729 has also provided thermosetting compositions which can be used in the electrical field. These compositions, comprising two types of epoxy resins and inorganic fillers in a large amount, are based on the use of a combination of an anhydride curing agent and of a specific curing accelerator of imidazole, amidine or aminopyridine type corresponding to specific structures (I) to (IV).

Insulators, which constitute safety devices on electrical circuits, are subject to very exacting specifications in terms of electrical insulation, of lifetime and of resistance to damage. In point of fact, a typical disadvantage associated with the use of epoxy resins is their tendency to crack, either at low temperature, as a result of the difference in the thermal expansion coefficients of the epoxy resin and of the metal which it coats, or at higher temperature, as a result of the vaporization of the water trapped in the resin. These cracks promote the development of electric arcs which can generate a fire. The formation of these cracks is related to the high crosslinking density of epoxy resins, which makes them a material which is not very deformable and not very tolerant of thermal stresses. Their propagation is promoted by the not very ductile nature of epoxy resins.

In view of the impossibility of remelting epoxy resins, insofar as the reactions which have resulted in their formation are irreversible, it is impossible to repair these materials once they are cracked. For this reason, the entire installation consisting of the insulator, the connectors and the cables must be dismantled and replaced, which results in high costs of maintenance and of resin/metal separation in specialist recycling centers.

The need thus remains to have available materials exhibiting the advantageous properties of epoxy resins without their disadvantages, that is to say which exhibit good mechanical and insulating properties while being capable of relaxing, by simple heat treatment, the stresses generated during their operation by temperature differences, by mechanical loads or by chemical attacks. It would thus be possible to completely or partially repair the cracks formed in the material.

In point of fact, it became apparent to the applicant company that this need might be satisfied by using, instead of the epoxy resins conventionally employed in insulators, vitrimer materials.

Vitrimer materials exhibit both the mechanical and solvent-resistance properties of thermoset resins and the ability to be reshaped and/or repaired of thermoplastic materials. These polymer materials are capable of indefinitely changing from a solid state to a viscoelastic liquid, like glass.

The specific properties of vitrimers are related to the ability of their network to become reorganized above a certain temperature, without modifying the number of intramolecular bonds or becoming depolymerized, under the effect of internal exchange reactions. These reactions result in relaxation of the stresses within the material, which becomes malleable, while retaining its integrity and while remaining insoluble in any solvent. These reactions are rendered possible by the presence of a catalyst. In the case of vitrimers of epoxy-anhydride type, as in that of vitrirners of epoxy-acid type, obtained from a thermosetting resin of epoxy type and from a curing agent of anhydride or acid type respectively, it has been suggested to use, as catalyst, a zinc, tin, magnesium, cobalt, calcium, titanium or zirconium metal salt, preferably zinc acetylacetonate (WO 2012/101078; WO 2011/151584), in addition, provision has been made to use TBD as catalyst in systems based on epoxy resin and acid curing agent (M. Capelot et al., ACS Macro Lett, 2012, 1, 789-792).

The inventors have clearly demonstrated that the use of nonmetallic organic catalysts makes it possible to obtain vitrimer materials of use in the manufacture of insulators.

### DEFINITIONS

“Thermosetting” resin is understood to mean a monomer, oligomer, prepolymer, polymer or any macromolecule capable of being crosslinked chemically. More preferably, it is understood to mean a monomer, oligomer, prepolymer, polymer or any macromolecule capable of being crosslinked chemically when it is reacted with a curing agent (also known as crosslinking agent) in the presence of a source of energy, for example of heat or of radiation, and optionally of a catalyst.

“Thermoset” resin or resin “in the thermoset state” is understood to mean a thermosetting resin crosslinked chemically so that its gel point is reached or exceeded. “Gel point” is understood to mean the degree of crosslinking starting from which the resin is virtually no longer soluble in the solvents. Any method conventionally used by a person skilled in the art can be employed to confirm it. It will be possible, for example, to employ the test described in the application WO 97/23516, page 20. A resin is regarded as thermoset within the meaning of the invention if its gel content, that is to say the percentage of its residual weight after placing in solvent, relative to its initial weight before placing in solvent, is equal to or greater than 75%.

The term “curing agent” denotes a crosslinking agent capable of crosslinking a thermosetting resin. It is in this instance a generally polyfunctional compound carrying functional groups of anhydride and/or acid type which are capable of reacting with reactive functional groups carried by the resin.

“Nonmetallic organic catalyst” is understood to mean a catalyst comprising at least carbon and hydrogen atoms and optionally other atoms chosen from N, O, S and/or P. This definition consequently excludes organometallic catalysts and also organic metal salts, including in particular zinc, tin, magnesium, cobalt, calcium, titanium and/or zirconium atoms.

“Vitrimer-effect catalyst” is understood to mean a catalyst which facilitates the internal exchange reactions within a thermoset resin so as to render it deformable.

This catalyst can in particular satisfy the test described in the publication WO2012/101078, on pages 14-15.

When reference is made to intervals, the expressions of the type “ranging from . . . to . . . ” include the limits of the interval. The expressions of the “of between . . . and . . . ” or “between . . . and . . . ” type exclude the limits of the interval.

### SUMMARY OF THE INVENTION

A subject matter of the invention is the use, in the manufacture of electrical insulation parts, of a composition including, apart from a thermosetting resin of epoxy type and a curing agent, at least one vitrimer-effect nonmetallic organic catalyst at a content ranging from 0.1 to 10 mol %, relative to the molar amount of epoxy functional groups present in the thermosetting resin.

Advantageously, the vitrimer-effect catalyst is chosen from the compounds of guanidine type corresponding to the formula (I):

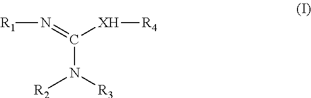

in which:
X denotes a nitrogen atom,
R₁ denotes a hydrogen atom, a C₁-C₆ alkyl group or a phenyl group which can be substituted by a C₁-C₄ alkyl group,
R₂, R₃ and R₄ independently denote a hydrogen atom, a C₁-C₆ alkyl group, or a phenyl group which can be substituted by a C₁-C₄ alkyl group, or an acetyl group, or R₁ and R₂ form, together and with the atoms to which they are bonded, an unsaturated heterocycle and/or R₃ and R₄ form, together and with the atoms to which they are bonded, a saturated or unsaturated heterocycle.

Another subject matter of the invention is a process for the manufacture of electrical insulation parts, comprising:
a) the preparation under hot conditions of a composition including a thermosetting resin of epoxy type, a curing agent and at least one vitrimer-effect nonmetallic organic catalyst, starting from the composition as defined above,
b) optionally the bringing of the composition resulting from stage a) into contact with at least one electrically conducting element,
c) the shaping of the composition resulting from stage a),
d) the application of energy which makes possible the curing of the resin,
e) the cooling of the thermoset resin.

Another subject-matter of the invention is an electrical insulation part obtained according to this process.

### DETAILED DESCRIPTION

As indicated above, the composition used according to the invention includes a vitrimer-effect nonmetallic organic catalyst. It is understood that this catalyst is present, in the composition of the invention, in addition to the catalysts liable to be already present intrinsically in the thermosetting resin and/or in the curing agent, as a result of their preparation, which can be carried out in the presence of a low content of catalysts, or in addition to the conventional catalysts of epoxide ring opening.

It is preferable to use, as vitrimer-effect catalyst, the compounds of guanidine type corresponding to the formula (I):

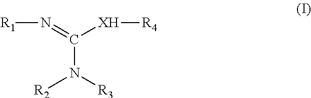

in which:
X denotes a nitrogen atom,
R₁ denotes a hydrogen atom, a C₁-C₆ alkyl group or a phenyl group which can be substituted by a C₁-C₄ alkyl group,
R₂, R₃ and R₄ independently denote a hydrogen atom, a C₁-C₆ alkyl group, or a phenyl group which can be substituted by a C₁-C₄ alkyl group, or an acetyl group, or R₁ and R₂ form, together and with the atoms to which they are bonded, an unsaturated heterocycle and/or R₃ and R₄ form, together and with the atoms to which they are bonded, a saturated or unsaturated heterocycle.

It is preferable for R₁ and R₂ to form, together and with the atoms to which they are bonded, an unsaturated heterocycle and for R₃ and R₄ to form, together and with the atoms to which they are bonded, a saturated or unsaturated, preferably saturated, heterocycle.

It is preferable for the C₁-C₆ alkyl or phenyl groups not to be substituted. Examples of catalysts of guanidine type which can be used in the present invention are as follows:

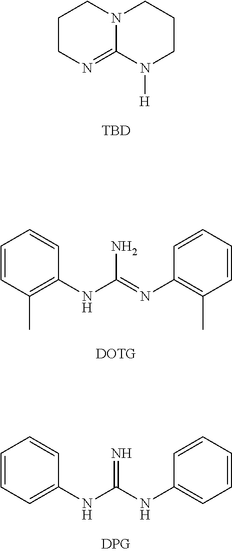 [SMILES: C1CN=C2NCCCN2C1 ; "TBD" ; Cc1ccccc1/N=C(\N)Nc1ccccc1C ; N=C(Nc1ccccc1)Nc1ccccc1]

Preferably, the catalyst of guanidine type is triazabicyclodecane (TBD).

According to one embodiment of the invention, the catalyst represents from 0.1 to 10 mol %, preferably from 0.1 to less than 5 mol %, more preferably from 0.5 to 2 mol %, relative to the molar amount of epoxy functional groups present in said thermosetting resin.

The composition according to the invention comprises at least one thermosetting resin curing agent, referred to as “acid curing agent”, which can be of carboxylic acid anhydride type, that is to say comprising at least one —C(O)—O—C(O)— functional group, or of acid type, comprising at least two carboxylic acid —C(O)OH functional groups. According to one embodiment, the acid curing agent comprise at least three acid functional groups (whether they are in the free carboxylic acid or acid anhydride form). This makes it possible to create a three-dimensional network when such a curing agent is employed to crosslink a thermosetting resin.

It is preferable according to the invention to use a curing agent of carboxylic acid anhydride type. This is because the epoxy-anhydride reactions are sufficiently slow to make possible the preparation of bulk parts or the manufacture of composites by filament winding or pultrusion and they limit the release of heat during the formation of the resin. In addition, epoxy-anhydride resins have very low degrees of shrinkage, so that they minimize the residual stresses in the parts produced and thus the risks of breaking. Finally, their glass transition temperature, which can be easily adjusted, is sufficiently high to guarantee the dimensional stability of the parts during the use.

Mention may in particular be made, as curing agents of anhydride type, of cyclic anhydrides, such as, for example, phthalic anhydride, nadic or methylnadic anhydride, dodecenylsuccinic anhydride (DDSA) or glutaric anhydride; partially or completely hydrogenated aromatic anhydrides, such as tetrahydrophthalic or methyltetrahydrophthalic anhydride, hexahydrophthalic or methylhexahydrophthalic anhydride; and their mixtures.

Mention may also be made, as curing agents of anhydride type, of succinic anhydride, maleic anhydride, trimellitic anhydride, the adduct of trimellitic anhydride and of ethylene glycol, chlorendic anhydride, tetrachlorophthalic anhydride, pyromellitic dianhydride (PMDA), the dianhydride of 1,2,3,4-cyclopentanetetracarboxylic acid, the polyanhydrides of aliphatic acids, such as polyazelaic polyanhydride, polysebacic anhydride, and their mixtures.

Use may in particular be made of the anhydrides of following formulae, and their mixtures:

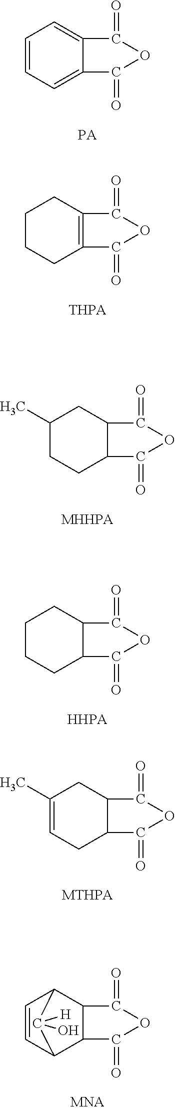

and more preferably MTHPA.

Mention may also be made, as curing agent of anhydride type, of the curing agent with the commercial reference HY905 sold by Huntsman, which is a liquid mixture of several anhydrides.

Mention may be made, as acid curing agents which can be used in accordance with the invention, of carboxylic acids comprising from 2 to 40 carbon atoms, fatty acid derivatives and their mixtures.

Use may also be made, as acid curing agents, of linear diacids, such as glutarie, adipic, pimelic, subaric, azelaic, sebacic, succinic and dodecanedioic acids and their homologs of higher weights; and their mixtures.

Use may also be made, as acid curing agents, of aromatic diacids, such as ortho-, meta- or para-phthalic acid, trimellitic acid, terephthalic acid or naphthalenedicarboxylic acid, and also their more or less alkylated and/or partially hydrogenated derivatives, for example (methyl)tetrahydrophthalic acid, (methyl)hexahydrophthalic acid or (methyl)nadic acid; and their mixtures.

“Fatty acid derivative”, with reference to the acid curing agent, is preferably understood to mean a fatty acid, a fatty acid ester, a triglyceride, an ester of fatty acid and of fatty alcohol, a fatty acid oligomer, in particular a fatty acid dimer (oligomer of two identical or different monomers) or a fatty acid trimer (oligomer of three identical or different monomers), and their mixtures.

Use may thus be made, as acid curing agents, of fatty acid trimers or a mixture of fatty acid dimers and trimers, advantageously comprising from 2 to 40 carbon atoms, advantageously of vegetable origin. These compounds result from the oligomeraization of unsaturated fatty acids, such as undecylenic, myristoleic, palmitoleic, oleic, linoleic, linolenic, ricinoleic, eicosenoic or docosenoic acid, which are normally found in pine, rapeseed, corn, sunflower, soybean, grapeseed, linseed and jojoba oils, and also eicosapentaenoic and docosahexaenoic acids, which are found in fish oils; and their mixtures.

Mention may be made, as example of fatty acid trimer, of the compound of the following formula, which illustrates a cyclic trimer resulting from fatty acids having 18 carbon atoms, it being known that the compounds available commercially are mixtures of steric isomers and of positional isomers of this structure, optionally partially or completely hydrogenated.

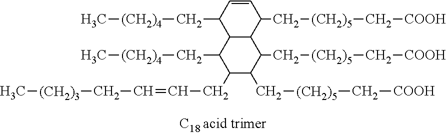

Use may be made, for example, of a mixture of fatty acid oligomers containing linear or cyclic C₁₈ fatty acid dimers, trimers and monomers, said mixture being predominant in dimers and trimers and containing a low percentage (usually less than 5%) of monomers. Preferably, said mixture comprises:
0.1 to 40% by weight, preferably 0.1 to 5% by weight, of identical or different fatty acid monomers,
0.1 to 99% by weight, preferably 18 to 85% by weight, of identical or different fatty acid dimers, and
0.1 to 90% by weight, preferably 5 to 85% by weight, of identical or different fatty acid trimers.

Mention may be made, as examples of fatty acid dimer/trimer mixtures (% by weight), of:
Pripol® 1017 from Croda, mixture of 75-80% of dimers and 18-22% of trimers with of the order of 1-3% of monomeric fatty acids,
Pripol® 1048 from Croda, mixture of 50/50% of dimer/trimers,
Pripol® 1013 from Croda, mixture of 95-98% of dimers and of 2-4% of trimers with a maximum of 0.2% of monomeric fatty acids,
Pripol® 1006 from Croda, mixture of 92-98% of dimers and of a maximum of 4% of trimers with a maximum of 0.4% of monomeric fatty acids,
Pripol® 1040 from Croda, mixture of fatty acid dimers and trimers with at least 75% of trimers and less than 1% of monomeric fatty acids,
Unidyme® 60 from Arizona Chemicals, mixture of 33% of dimers and of 67% of trimers with less than 1% of monomeric fatty acids,
Unidyme® 40 from Arizona Chemicals, mixture of 65% of dimers and of 35% of trimers with less than 1% of monomeric fatty acids,
Unidyme® 14 from Arizona Chemicals, mixture of 94% of dimers and of less than 5% of trimers and other higher oligomers with the order of 1% of monomeric fatty acids,
Empol® 1008 from Cognis, mixture of 92% of dimers and of 3% of higher oligomers, essentially trimers, with the order of 5% of monomeric fatty acids,
Empol® 1018 from Cognis, mixture of 81% of dimers and of 14% of higher oligomers, including essentially trimers, with the order of 5% of monomeric fatty acids,
Radiacid® 0980 from Oleon, mixture of dimers and trimers with at least 70% of trimers.

The Pripol®, Unidyme®, Empol®, and Radiacid® products comprise C₁₈ fatty acid monomers and fatty acid oligomers corresponding to multiples of C₁₈.

Mention may also be made, as acid curing agents, of polyoxyalkylenes (polyoxyethylene, polyoxypropylene, and the like) comprising carboxylic acid functional groups at the ends, polymers comprising carboxylic acid functional groups at the ends, having a branched or unbranched structure, advantageously chosen from polyesters and polyamides and preferably from polyesters, and their mixtures.

Mention may also be made, as acid curing agent, of phosphoric acid.

The composition according to the invention also comprises at least one thermosetting resin comprising at least one and advantageously several epoxide functional groups and optionally at least one and advantageously several free hydroxyl functional groups and/or ester functional groups. Such a resin will be denoted by “epoxy resin”.

Advantageously, the epoxy resin represents at least 10% by weight, at least 20% by weight, at least 40% by weight, at least 60% by weight, indeed even 100% by weight, of the total weight of thermosetting resin present in the composition.

There are two main categories of epoxy resins: epoxy resins of glycidyl type and epoxy resins of non-glycidyl type. The epoxy resins of glycidyl type are themselves categorized into glycidyl ether, glycidyl ester and glycidyl amine. The non-glycidyl epoxy resins are of aliphatic or cycloaliphatic type. The glycidyl epoxy resins are prepared by a condensation reaction of a diol, diacid or diamine with epichlorohydrin. The non-glycidyl epoxy resins are formed by peroxidation of the olefinic double bonds of a polymer.

Among the glycidyl epoxy ethers, bisphenol A diglycidyl ether (BADGE) represented below is the most commonly used.

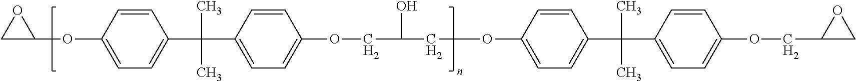

The resins based on BADGE have excellent electrical properties, a low shrinkage, good adhesion to numerous metals, good resistance to moisture and to mechanical impacts, and good thermal resistance.

The properties of the BADGE resins depend on the value of the degree of polymerization n, which itself depends on the stoichiometry of the synthesis reaction. As a general rule, n varies from 0 to 25.

Novolac epoxy resins (the formula of which is represented below) are glycidyl ethers of novolac phenolic resins. They are obtained by reaction of phenol with formaldehyde in the presence of an acid catalyst to produce a novolac phenolic resin, followed by a reaction with epichlorohydrin in the presence of sodium hydroxide as catalyst.

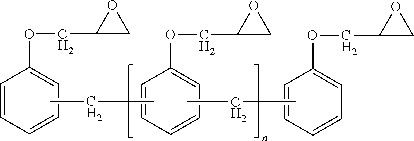

Novolac epoxy resins generally comprise several epoxide groups. The multiple epoxide groups make it possible to produce thermoset resins with a high crosslinking density. Novolac epoxy resins are widely used to manufacture materials for microelectronics due to their superior resistance at an elevated temperature, their excellent suitability for molding and their superior mechanical, electrical, heat resistance and moisture resistance properties.

The thermosetting resin which can be used in the present invention can, for example, be chosen from: novolac epoxy resins, bisphenol A diglycidyl ether (BADGE), hydrogenated bisphenol A diglycidyl ether, bisphenol F diglycidyl ether, tetraglycidyl methylene dianiline, pentaerythritol tetraglycidyl ether, trimethylolpropane triglycidyl ether (TMPTGE), tetrabromobisphenol A diglycidyl ether, or hydroquinone diglycidyl ether, ethylene glycol diglycidyl ether, propylene glycol diglycidyl ether, butylene glycol diglycidyl ether, neopentyl glycol diglycidyl ether, 1,4-butanediol diglycidyl ether, 1,6-hexanediol diglycidyl ether, cyclohexanedimethanol diglycidyl ether, polyethylene glycol diglycidyl ether, polypropylene glycol diglycidyl ether, polytetratnethylene glycol diglycidyl ether, resorcinol diglycidyl ether, bisphenol A polyethylene glycol diglycidyl ether, bisphenol A polypropylene glycol diglycidyl ether, terephthalic acid diglycidyl ester, poly(glycidyl acrylate), poly(glycidyl methacrylate), epoxidized polyunsaturated fatty acids, epoxidized vegetable oils, in particular epoxidized soybean oil, epoxidized fish oils and epoxidized limonene; versatic acid glycidyl esters, such as those sold under the name Cardura® E8, E10 or E12 by Momentive (Cardura® E10 of CAS 26761-45-5); epoxidized cycloaliphatic resins sold under the name Araldite® CY179, CY184, MY0510 or MY720 by BASF, the CY179 and CY184 resins respectively corresponding to the following formulae:

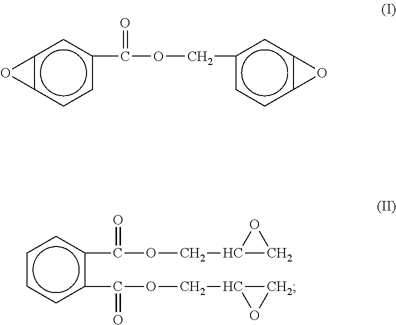

triglycidyl isocyanurate (TGIC); alkoxylated glycidyl (meth)acrylates, glycidyl (meth)acrylate; C₈-C₁₀ alkyl glycidyl ethers, C₁₂-C₁₄ alkyl glycidyl ethers, neodecanoic acid glycidyl ester, butyl glycidyl ether, cresyl glycidyl ether, phenyl glycidyl ether, p-nonylphenyl glycidyl ether, p-(t-butyl)phenyl glycidyl ether, 2-ethylhexyl glycidyl ether, acid dimer diglycidyl ester, castor oil polyglycidyl ether, and the mixtures of the abovementioned resins.

Advantageously, it is more particularly chosen from: BADGE, bisphenol F diglycidyl ether, novolac resins, TMPTGE, 1,4-butanediol diglycidyl ether, Araldite®CY184 of formula (II) above, TGIC, epoxidized soybean oil and their mixtures. More preferably still, it is BADGE.

According to one embodiment, the composition is composed of the vitrimer-effect catalyst, the curing agent and an epoxy thermosetting resin, as are defined above. According to this embodiment, the number of moles of catalyst can range from 0.1 to 10%, preferably from 0.5 to 5%, preferably from 0.5 to 2%, relative to the number of moles of anhydride functional groups of the curing agent. The number of moles of epoxide functional groups of the resin can range from 50 to 300%, preferably from 100 to 200%, preferably from 125 to 150%, relative to the number of moles of anhydride functional groups of the curing agent.

The composition of the invention can optionally comprise one or more additional compounds, insofar as their presence does not detrimentally affect the advantageous properties which result from the invention. Examples of such additional compounds are: polymers, pigments, dyes, insulating fillers, plasticizers, long or short and woven or nonwoven fibers, flame-retardant agents, antioxidants, lubricants, wood, glass, metals and their mixtures.

Advantageously, the content of thermosetting resin and of curing agent ranges from 10 to 90% by weight, in particular from 20 to 80% by weight, indeed even from 30 to 70% by weight, relative to the total weight of the composition, the remainder to 100% being contributed by the catalyst and optionally by additional compounds chosen from the abovementioned compounds.

Mention may be made, among the polymers which can be employed as a mixture with the composition of the invention, of: elastomers, thermoplastics, thermoplastic elastomers or impact additives.

Pigments is understood to mean colored particles which are insoluble in the composition of the invention. Mention may be made, as pigments which can be used according to the invention, of phthalocyanines, anthraquinones, quinacridones, dioxazines, azo pigments or any other organic pigment, natural pigments (madder, indigo, murex, cochineal, etc.) and mixtures of pigments.

Dyes is understood to mean molecules which are soluble in the composition of the invention and which have the ability to absorb a portion of the visible radiation. Mention may be made, as example of insulating fillers which can be included in the composition, of those chosen from: inorganic oxides, inorganic hydroxides and inorganic oxyhydroxides, such as silica, quartz, silicates, such as clays, talc and kaolin, alumina or titanium oxide; calcium carbonate; nitrides, such as silicon nitride, boron nitride and aluminum nitride; carbides, such as silicon carbide; whiskers; and their mixtures.

These fillers can represents from 5 to 80% by weight, preferably from 10 to 60% by weight and more preferably from 20 to 50% by weight, indeed even from 20 to 40% by weight, with respect to the total weight of the composition.

Mention may be made, among the fibers which can be employed in the composition in the invention, of: glass fibers, carbon fibers, polyester fibers, polyamide fibers, aramid fibers, cellulose and nanocellulose fibers or also plant fibers (flax, hemp, sisal, bamboo, and the like) and their mixtures.

The presence, in the composition of the invention, of pigments, dyes or fibers capable of absorbing radiation, or their mixtures, can be used to provide for the heating of a material or of an object manufactured from such a composition, by means of a source of radiation, such as a laser.

The additional compounds can also be chosen from one or more other catalysts and/or curing agents of any nature known to a person skilled in the art as playing these roles insofar as they do not detrimentally affect the advantageous properties resulting from the invention. They will be denoted by “supplementary catalyst” and “supplementary curing agent”.

According to preferred form of implementation of the invention, the composition described here additionally includes one or more supplementary catalysts which are specific to epoxide opening, such as:
tertiary amines, optionally blocked, such as, for example: 2,4,6-tris(dimethylaminomethyl)phenol (for example sold under the name Ancamine), o-(dimethylaminomethyl)phenol, benzyldimethylamine (BDMA), 1,4-diazabicyclo[2.2.2]octane (DABCO) or methyltribenzylammonium chloride,
imidazoles, such as 2-methylimidazole (2-MI), 2-phenylimidazole (2-PI), 2-ethyl-4-methylimidazole (EMI), 1-propylimidazole, 1-ethyl-3-methylimidazolium chloride or 1-(2-hydroxypropyl)imidazole,
phosphoniums: tetraalkyl- and alkyltriphenylphosphonium halides,
amine salts of polyacids, aniline/formaldehyde condensates, N,N-alkanolamines, trialkanolamine borates, fluoroborates, such as boron trifluoride monoethylamine (BF₃-MEA), organosubstituted phosphenes, quaternary monoimidazoline salts, mercaptans or polysulfides,
and their mixtures.

Preferably, the epoxide opening catalyst is chosen from: tertiary amines, imidazoles, and their mixtures.

(Hetero)aromatic amines, such as 2-methylimidazole and tris(dimethylaminomethyl)phenol, are more particularly preferred for use in this invention.

This supplementary epoxide opening catalyst is advantageously employed in the composition in a proportion of 0.1 to 5 mol %, with respect to the number of moles of epoxide functional groups carried by the thermosetting resin.

Use may also be made of one or more supplementary vitrimer-effect catalysts chosen from the catalysts cited in the applications WO2011/151584, WO2012/101078 and WO 2012/152859, still insofar as their presence does not detrimentally affect the advantageous properties resulting from the invention.

The supplementary vitrimer-effect catalysts can, for example, be present in the composition of the invention in the proportion of 0.1 to 10% by weight and preferably of 0.1 to 5% by weight, relative to the total weight of the composition.

Furthermore, the use of a supplementary curing agent makes it possible to obtain, for the materials manufactured in fine, a broad range of mechanical properties at ambient temperature (for example control of the glass transition temperature and/or of the modulus of a thermoset resin).

Mention may be made, as examples of supplementary curing agents, of epoxy resin curing agents, in particular those chosen from amines, polyamides, phenolic resins, isocyanates, polymercaptans, dicyanodiamides and their mixtures.

In particular, a supplementary curing agent of amine type can be chosen from primary or secondary amines having at least one —NH₂ functional group or two NH functional groups and from 2 to 40 carbon atoms. These amines can, for example, be chosen from aliphatic amines, such as diethylenetriamine, triethylenetetramine, tetraethylenepentamine, dihexylenetriamine, cadaverine, putrescine, hexanediamine, spermine or isophoronediamine, and also aromatic amines, such as phenylenediamine, diaminodiphenylmethane, diaminodiphenyl sulfone, methylenebischlorodiethylaniline, meta-xylylenediamine (MXDA) and its hydrogenated derivatives, such as 1,3-bis(aminomethy)lcyclohexane (1,3-BAC); and their mixtures.

A supplementary curing agent of amine type can also be chosen from polyetheramines, for example the Jeffamine products from Huntsman, optionally as mixtures with other supplementary curing agents.

Mention may be made, as preferred supplementary curing agents, of diethylenetriamine, triethylenetetramine, hexanediamine and their mixtures.

According to a preferred embodiment of the invention, the composition described here additionally includes at least one polyol, in particular a linear or branched polyhydroxyalkane, such as glycerol, trimethylolpropane or pentaerythritol. Other types of polyols can also be used. This is because it has been observed that the addition of this compound to the reaction mixture makes it possible to further improve the vitrimer properties of the material, that is to say to obtain a material capable of more completely and more rapidly relaxing the stresses after application of a deformation.

### Process for the Preparation of the Composition

The compounds of the composition used according to the invention are either commercially available or can be easily synthesized by a person skilled in the art from commercially available starting materials.

This composition can be obtained by simply bringing into contact the compounds which it includes. This operation of bringing into contact is preferably carried out at a temperature ranging from 15° C. to 130° C., in particular from 50° C. to 125° C. The contacting operation can be carried out with or without homogenization means.

According to a specific embodiment, the process comprises a first stage during which the catalyst is preintroduced into the resin or the curing agent, preferably into the curing agent. The catalyst can then be in the form of a dispersion, if it is a powder, or of a solution. This dispersing or dissolving can be carried out at ambient temperature or under hot conditions in order to obtain the desired viscosity characteristics.

The composition used according to the invention can be prepared from a kit comprising at least:
a first composition comprising the catalyst, alone or with the curing agent or the thermosetting resin;
optionally a second composition comprising the curing agent;
optionally a third composition comprising the thermosetting resin.

The different compositions can be stored together or separately. It is also possible to store together some of the compositions while keeping them separate from the other compositions.

The different compositions are generally stored at ambient temperature. Preferably, when the second and third compositions are both present in the kit, they are in a packaging appropriate for preventing a crosslinking reaction between the thermosetting resin and the curing agent from taking place without intervention of an operator.

The packaging can consist of a container comprising two, indeed even three, internal compartments making possible the separate storage of each of the compositions. According to an alternative form, the kit can consist of one and only one container, containing a mixture in appropriate amounts of the two or three compositions. In the latter case, the intervention by the operator is advantageously restricted to heating.

A means may be provided which makes it possible to bring into contact the contents of the different compartments, advantageously so as to make it possible to initiate the crosslinking in the container.

It is also possible to provide a kit consisting of several separate flasks combined in one and the same packaging and each comprising the appropriate amounts of each of the compositions for the preparation of the composition of the invention, so as to save the user from carrying out weighing and/or metering operations.

### Uses

The composition described above is used in the manufacture of electrical insulation parts.

The latter can in particular be chosen from: an electrical insulator of electrical or electronic components, in the molded form or in the form of a matrix, coating, seal or adhesive, and in particular an adhesive for printed patch boards, a matrix resin for prepregs, or a resin for the coating or encapsulation of transistors, diodes, transformers or integrated circuits.

The electrical insulation parts can be manufactured by a conventional process for employing epoxy resins, such as, for example, molding, resin transfer molding (RTM), filament winding or pultrusion. In these cases, the parts obtained are subsequently assembled in more complex systems of insulators and/or brought into contact with conducting components. Usually, for electrical applications, the vitrimer formulation comprises fillers of silica or clay type. It is also very often used to obtain composite materials, based, for example, on glass fibers, with one of the abovementioned processes.

Another method of obtaining electrically insulating systems consists in embedding an electrical or electronic system in the thermosetting formulation of vitrimer type, by processes conventionally used for this type of operation: gravity molding, low-pressure injection molding or potting.

The process for the manufacture of these insulation parts then comprises the following stages:
a) the preparation under hot conditions of a composition including a thermosetting resin of epoxy type, a curing agent and at least one vitrimer-effect nonmetallic organic catalyst, from the composition described above,
b) optionally the bringing of the composition resulting from stage a) into contact with at least one electrically conducting element,
c) the shaping of the composition resulting from stage a),
d) the application of energy making possible the curing of the resin,
e) the cooling of the thermoset resin.

This thermoset resin advantageously exhibits:
a glass transition temperature (Tg) of between 50 and 170° C., preferably between 70 and 160° C., and more preferably between 100 and 150° C.,
a relaxation time τ necessary in order to obtain a standardized stress value equal to 1/e at a temperature equal to Tg+100° C. and/or to 200° C., which is less than 5000 seconds, preferably less than 2000 seconds, and more preferably less than 1000 seconds,
a percentage of stresses σ relaxed after 5000 seconds at a temperature equal to Tg+100° C. and/or to 200° C., which is at least 80%, preferably at least 90%, more preferably at least 95%, indeed even 100%,
a storage modulus (G′) at the rubbery plateau, for example at a temperature of between 150 and 200° C., of greater than 5 MPa, preferably of greater than or equal to 10 MPa, indeed even of greater than or equal to 15 MPa.

These quantities are measured according to the protocols indicated in the examples below. The characteristics of the thermoset resin are particularly well suited to the specifications of the electrical insulation parts.

### Process for Deforming or Repairing

The thermoset resins obtained as described above exhibit the advantage of exhibiting a slow variation in viscosity over a broad range of temperatures, which renders the behavior of the insulation parts obtained from these resins comparable with that of inorganic glasses and makes it possible to apply to them deformation processes which cannot be applied to conventional thermosets.

These parts can thus be fashioned by applying stresses of the order of 1 to 10 MPa without, however, flowing under their own weight.

In the same way, these parts can be deformed at a temperature greater than the temperature Tg, and then, in a second step, the internal stresses can be removed at a higher temperature.

The application of heat can also make it possible to repair cracks by bringing the separated surfaces back into contact under the effect of a pressure.

It should be noted that no depolymerization is observed at high temperatures and the insulation parts of the invention retain their crosslinked structure. This property makes possible the repair of parts which will be found cracked, indeed even fractured into at least two parts, by a simple welding of these parts together. No mold is necessary to maintain the shape of the parts of the invention during the repairing process at high temperatures.

Thus, the insulation parts as described above can be deformed according to a process comprising the application to the parts of a mechanical stress at a temperature (T) greater than the glass transition temperature. The assembling, the welding, the repairing and the recycling constitute a specific case of this deformation process. Preferably, in order to make the deformation possible in a period of time compatible with an industrial application, the deformation process comprises the application, to the insulation parts of the invention, of a mechanical stress at a temperature (T) greater than the glass transition temperature Tg of the thermoset resin which they contain.

Usually, such a deformation process is followed by a stage of cooling down to ambient temperature, optionally with application of at least one mechanical stress. “Mechanical stress” is understood to mean, within the meaning of the present invention, the application of a mechanical force, locally or over all or part of the part, this mechanical force aiming at a shaping or a deformation of the part. Mention may be made, among the mechanical stresses which can be employed, of: pressure, molding, kneading, extrusion, blowing, injection, stamping, twisting, bending, traction and shearing. It can concern, for example, a twisting applied to the part of the invention in the form of a strip. It can concern a pressure applied using a plate or a mold to one or more faces of a part of the invention, the stamping of a pattern in a slab or a sheet. It can also concern a pressure exerted at the same time on two parts of the invention in contact with one another so as to bring about welding of these parts. The mechanical stress can also consist of a multiplicity of separate stresses, of the same or different nature, applied simultaneously or successively to all or part of the parts of the invention, or in localized fashion.

This deformation process can include a stage of mixing or of agglomeration of the insulation part of the invention with one or more additional components chosen from those mentioned above and in particular: polymers, pigments, dyes, fillers, plasticizers, long or short and woven or nonwoven fibers, frame-retardant agents, antioxidants or lubricants.

The rise of the temperature in the deformation process can be carried out by any known means, such as heating by conduction, convection, induction, spot heating, infrared, microwave or radiant heating. The means which make it possible to bring about a rise in temperature for the implementation of the processes of the invention comprise: an oven, a microwave oven, a heating resistance, a flame, an exothermic chemical reaction, a laser beam, an iron, a hot air gun, an ultrasonic bath, a heating punch, and the like. The rise in temperature may or may not be carried out stepwise and its duration is adjusted to the result expected.

Although the resin does not flow during its deformation, by virtue of the internal exchange reactions, by choosing an appropriate temperature, an appropriate heating time and appropriate cooling conditions, the new shape can be devoid of any residual stress. The path is thus not weakened or fractured by the application of the mechanical stress. Furthermore, if the deformed part is subsequently reheated, it will not return to its first shape. This is because the internal exchange reactions which occur at high temperature promote a reorganization of the crosslinking points of the network of the thermoset resin so as to cancel out the mechanical stresses. A sufficient heating time makes it possible to completely cancel out these mechanical stresses internal to the part which have been caused by the application of the external mechanical stress.

This method thus makes it possible to obtain stable complex shapes, which are difficult, indeed even impossible, to obtain by molding, from simpler elementary shapes. In particular, it is very difficult to obtain, by molding, shapes resulting from twisting. Additionally, the choice of appropriate conditions of temperature, of duration of heating under stress and of cooling makes it possible to convert a part according to the invention while controlling the persistence of certain internal mechanical stresses within this part and then, if the part thus converted is subsequently reheated, a new controlled deformation of this part by controlled release of the stresses can be carried out.

### Recycling Processes

The insulation part obtained according to the invention can also be recycled:
either by direct treatment: for example, a broken or damaged part of the invention is repaired by a deformation process as described above and can thus regain its prior function of use or another function;
or the part is reduced to particles by application of mechanical grinding and the particles thus obtained are subsequently employed in a process for the manufacture of an insulation part in accordance with the invention. In particular, according to this process, the particles are simultaneously subjected to a rise in temperature and to a mechanical stress which allow them to be converted into an insulation part in accordance with the invention.

The mechanical stress which makes possible the conversion of the particles can, for example, comprise a compression in a mold, a kneading and/or an extrusion. This method makes it possible in particular, by the application of a sufficient temperature and of an appropriate mechanical stress, to mold new parts.

### EXAMPLES

The following examples illustrate the invention without limiting it.

### Example 1

### Synthesis of an Epoxy-Anhydride Network in the Presence of 1% of TBD

Several samples of vitrimer material were prepared as described below.

An epoxy resin of BADGE type (DER332 from Dow, Equivalent Epoxy Weight: 174 g/eq) in a form of a viscous liquid and also TBD (Aldrich) in a proportion of 1 mol % of catalyst per mole of epoxide functional groups were added to a beaker. The beaker was placed in an oil bath thermostatically controlled at 100-120° C. until the catalyst had completely dissolved in a resin in order to obtain a homogeneous and transparent mixture. Methyltetrahydrophthalic anhydride (MTHPA) (MW=166.18 g/mol) was then added to this mixture outside the bath and then the combined mixture was homogenized for a few minutes in the bath before being poured into a slightly silicone-treated hollow metal mold of 70×140×3 mm. The mold was rendered integral by a silicone seal with a metal plate covered with a Teflon coating, and then the combination was introduced into a heating press preadjusted to a temperature of 140° C. and placed at the start of curing at a pressure of 10 bar. The curing was carried out for 17 hours.

The above process was carried out using different molar ratios of the epoxide functional groups of the resin to the anhydride functional groups of the curing agent, namely:
a ratio of 1/0.5 for sample 1a,
a ratio of 1/0.8 for sample 1b,
a ratio of 1/1 for sample 1c.

### Example 2

### Mechanical Properties

The mechanical properties of the materials of example 1 and also of a material obtained in an identical way to example 1b, except that the TBD was replaced with an epoxide opening catalyst in the form of a tertiary amine which is conventionally used for the synthesis of epoxy-anhydride resins, 1,4-diazabicyclooetane (DABCO), were evaluated. This comparative sample will be denoted subsequently by “sample 2”.

Specifically, samples of these materials were first subjected to a dynamic mechanical analysis (DMA). To do this, a bar with dimensions of 10×30×3 mm was fixed between two pincers and stressed in rectangular torsion (imposed deformation of 0.05%) in an RDA3 device from Rheometric Scientific, with a frequency of 1 Hz, while carrying out a temperature sweep from 25 to 250° C. with a temperature gradient of PC/min. The Tα value was determined at the summit of the peak of the tan δ curve and is regarded below as the Tg of the sample, while the storage modulus G′ was determined on the rubbery plateau at 200° C.

The values shown in table 1 below were thus obtained.

TABLE 1

| Sample | 1a | 1b | 1c | 2 (comp) |
|---|---|---|---|---|
| Tg (° C.) | 130 | 148 | 148 | 110 |
| G′ (MPa) | 15 | 14 | 15 | 7 |

In addition, another sample of each of these materials was subjected to an experiment consisting in imposing, on a test specimen of 40×20×2 mm, a deformation under a stream of nitrogen, in three-point bending, using a Metravib device of DMA50N type, after the sample had been brought to a temperature equal to Tg+100° C. or to 200° C., and stabilized at this temperature for 5 min. The change in the stresses brought about in the material in order to keep the deformation constant is monitored for 5000 seconds and measured using a sensor. A force equal to zero is subsequently imposed on the sample and the deformation (recovery) of the sample is measured for an additional 5000 seconds. When the material retains the deformation which has been imposed on it, it is considered that all the stresses have been relaxed. The standardized stress (σ/σo) is subsequently plotted as a function of the time and, for each test, the relaxation time τ necessary in order to obtain a standardized stress value equal to 1/e, and also the percentage of relaxed stresses at 5000 seconds, hereinafter denoted by σ₅₀₀₀ₛ, are recorded.

The results obtained are collated in table 2 below.

TABLE 2

| Sample | 1a | 1b | 1c | 2 (comp) |
|---|---|---|---|---|
| τ (s) | 345 | 1015 | 1655 | >5000 |
| σ₅₀₀₀ₛ | 96 | 100 | 100 | 28 |
| (%) | | | | |

As emerges from this table, the composition according to the invention makes it possible to obtain materials capable of completely and rapidly relaxing their stresses, in contrast to the comparative material obtained without vitrimer-effect catalyst. It follows that only the materials obtained according to the invention exhibit vitrimer properties allowing them to be repaired by simple heating.

### Example 3

### Thermal Stability

The thermal stability of the material 1a of example 1 was evaluated. The measurement was carried out by TGA on a Perkin Elmer device of TGA7 type, a temperature sweep from 25° C. to 500° C. being carried out according to a gradient of 10° C./min. The temperature resulting in a loss of material of 1% was 305° C. In addition, the loss of material after 1 h at 250° C. amounted to only 1.5%. These results reflect the good thermal behavior of the materials according to the invention at the repairing and recycling temperatures.

1. A process for manufacturing an electrical insulation part, comprising using a composition comprised of a thermosetting resin of epoxy type, a curing agent, and at least one vitrimer-effect nonmetallic organic catalyst at a content ranging from 0.1 to 10 mol %, relative to the molar amount of epoxy functional groups present in the thermosetting resin, said catalyst being selected from compounds of guanidine type corresponding to the formula (I): 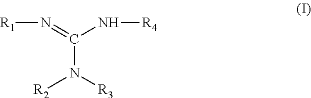
in which:
X denotes a nitrogen atom,
R₁ denotes a hydrogen atom, a C₁-C₆ alkyl group or a phenyl group which can be substituted by a C₁-C₄ alkyl group,
R₂, R₃ and R₄ independently denote a hydrogen atom, a C₁-C₆ alkyl group, or a phenyl group which can be substituted by a C₁-C₄ alkyl group, or an acetyl group,
or R₁ and R₂ form, together and with the atoms to which they are bonded, an unsaturated heterocycle and/or R₃ and R₄ form, together and with the atoms to which they are bonded, a saturated or unsaturated heterocycle.

2. The process as claimed in claim 1, wherein the thermosetting resin is bisphenol A diglycidyl ether (BADGE).

3. The process as claimed in claim 1, wherein the curing agent is selected from the group consisting of carboxylic acid anhydrides comprising at least one —C(O)—O—C(O)— functional group and acids comprising at least two carboxylic acid —C(O)OH functional groups.

4. The process as claimed in claim 1, wherein the vitrimer-effect catalyst is selected from triazabicyclodecane (TBD), di(ortho-tolyl)guanidine (DOTG) or 1,3-diphenyiguanidine (DPG).

5. The process as claimed in claim 1, wherein the catalyst represents from 0.1 to less than 5 mol %, relative to the molar amount of epoxy functional groups present in said thermosetting resin.

6. The process as claimed claim 1, wherein the composition additionally comprises at least one filler selected from the group consisting of: inorganic oxides, inorganic hydroxides and inorganic oxyhydroxides; calcium carbonate; nitrides; carbides; whiskers; and their mixtures.

7. The process as claimed in claim 6, wherein the fillers represent from 5 to 80% by weight, with respect to the total weight of the composition.

8. The process as claimed in claim 1, wherein the electrical insulation part is selected from: an electrical insulator of electrical or electronic components, in the molded form or in the form of a matrix, coating, seal or adhesive, an adhesive for printed patch boards, a matrix resin for prepregs, or a resin for the coating or encapsulation of transistors, diodes, transformers or integrated circuits.

9. The process of claim 1, comprising the stages of:
a) preparing under hot conditions of the composition.
b) optionally, bringing the composition resulting from stage a) into contact with at least one electrically conducting element,
c) shaping the composition resulting from stage a),
d) applying energy which makes possible the curing of the thermosetting resin to form a thermoset resin,
e) cooling the thermoset resin.

10. An electrical insulation part obtained according to the process as claimed in claim 9.

11. The process as claimed in claim 1, wherein the vitrimer-effect catalyst is triazabicyclodecane (TBD).

12. The process as claimed in claim 1, wherein the catalyst represents from 0.5 to 2 mol %, relative to the molar amount of epoxy functional groups present in said thermosetting resin.

13. The process as claimed in claim 1, wherein the composition additionally comprises at least one filler selected from the group consisting of: silica, quartz, silicates, clays, talc, kaolin, alumina, titanium oxide, calcium carbonate, silicon nitride, boron nitride and aluminum nitride, silicon carbide, and their mixtures.

14. The process as claimed in claim 6, wherein the fillers represent from 10 to 60% by weight, with respect to the total weight of the composition.

15. The process as claimed in claim 6, wherein the fillers represent from 20 to 50% by weight, with respect to the total weight of the composition.

16. The process as claimed in claim 1, wherein the catalyst is a carboxylic acid anhydride.
